(19) United States
(12) Patent Application Publication
(10) Pub. No.: US 2007/0048921 A1
(43) Pub. Date: Mar. 1, 2007

(54) Method for manufacturing semiconductor device

(75) Inventors: Takami Nagata, Kanagawa (JP); Hiroshi Furuta, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/503,203

(22) Filed: Aug. 14, 2006

(30) Foreign Application Priority Data
Aug. 29, 2005 (JP) 2005-247382

(51) Int. Cl. H01L 21/8238

(52) U.S. Cl. 438/199; 257/E29.264

(57) ABSTRACT

A method of manufacturing a semiconductor device includes performing a first etching process on a gate electrode layer to form a gate electrode of a first transistor group including a transistor pair, and performing a second etching process different from the first etching on the gate electrode layer to form a gate electrode of a second transistor group. Forming in this way enables characteristics of the transistor pair to be the same.

### BACKGROUND OF THE INVENTION

1. Field of the Invention

The present invention relates to a manufacturing method of a semiconductor device, and particularly to a method of manufacturing a plurality of devices having the same characteristics or a highly accurate device.

2. Description of Related Art

Conventionally in a semiconductor integrated circuit device, a multitude of pair field effect transistors (hereinafter referred to as MISFET) are used in a circuit. The pair MISFETs are used in a flip-flop circuit, a sense amplifier circuit in a memory storage, and a memory cell of a Static Random Access Memory (hereinafter referred to as SRAM), for example. Further, a difference in characteristics of those transistor pairs influence yield factor, performance and fluctuation in characteristics of an integrated circuit. In a semiconductor device where transistors are supposed to have the same characteristics, it is known that production tolerance produces a fluctuation in device characteristics. Furthermore in MISFET for example, besides a fluctuation in gate length (electrode width) between devices, a fluctuation of gate length in one gate electrode (LER: Line Edge Roughness) has become problematic. Production tolerance of MISFET by LER is disclosed in IEEE TRANSACTIONS ON SEMICONDUCTOR MANUFACTURING, vol. 17, August 2004, pp 357-361, Shiying Xion et al., for example.

Not only in a transistor but if there is a fluctuation generated in devices designed to have the same characteristic on a circuit, the fluctuation influence performance and yield factor of the circuit as with the above example. Furthermore in recent years, a passive device is formed using a metal wiring forming a wiring layer. Such a device is required to have a high accuracy in a device characteristic.

As an example of improving processing accuracy in forming a semiconductor device, a method of manufacturing a SRAM cell is disclosed in Japanese Unexamined Patent Application Publication No. 2000-91448. In a method disclosed in Japanese Unexamined Patent Application Publication No. 2000-91448, to prevent an end of a gate electrode from curling up, a separate process is provided to etch only the end.

Japanese Unexamined Patent Application Publication No. 63-3447 discloses a method of providing another process to form gate electrodes of NMOSFET and PMOSFET. Further, Japanese Unexamined Patent Application Publication No. 59-84571 discloses a method of forming a control gate after forming a floating gate in a non-volatile memory including EPROM. Japanese Unexamined Patent Application Publication No. 2002-10732 discloses a capacitance device as a passive device using a wiring.

It has now been discovered that in a method of manufacturing a semiconductor device described in the foregoing, there is no consideration given to fluctuation in characteristics of particular devices. Therefore, characteristics of individual transistors forming a transistor pair fluctuate, thereby generating a fluctuation in yield factor and performance of a semiconductor device. Furthermore, a passive device using a metal wiring is formed at the same time when the wiring layer is formed.

### SUMMARY OF THE INVENTION

According to an aspect of the present invention, there is provided a method of manufacturing a semiconductor device that includes performing a first etching process on a gate electrode layer to form a gate electrode of a first transistor group including a transistor pair, and performing a second etching process different from the first etching process on the gate electrode layer to form a gate electrode of a second transistor group. Forming in this way enables characteristics of the transistor pair to be the same.

According to another aspect of the present invention, there is provided a method of manufacturing a semiconductor device that includes performing a first etching process on a wiring layer to form a passive device formed by wiring layer, and performing a second etching process different from the first etch to form a line having a specified shape. Forming in this way enables a passive device to be highly accurate.

Providing a process to form only a particular device, it is possible to greatly suppress a fluctuation in characteristics of the particular device to.

### BRIEF DESCRIPTION OF THE DRAWINGS

The above and other objects, advantages and features of the present invention will be more apparent from the following description taken in conjunction with the accompanying drawings, in which:

FIG. 1 is a plan view showing a manufacturing method according to a first embodiment of the present invention;

FIG. 2 is a circuit diagram showing transistor pairs the present invention is applied in a SRAM cell;

FIG. 3 is a circuit diagram showing transistor pairs the present is applied in a differential circuit;

FIG. 4 is a circuit diagram showing transistor pairs the present invention is applied in an oscillation circuit;

FIG. 5 is a plan view showing a manufacturing method according to a first embodiment of the present invention;

FIG. 6 is a plan view showing a manufacturing method according to the first embodiment of the present invention;

FIG. 7 is a plan view explaining a manufacturing method according to a second embodiment of the present invention; and

FIGS. 8A to 8G are cross sectional views showing a manufacturing method according to the first embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

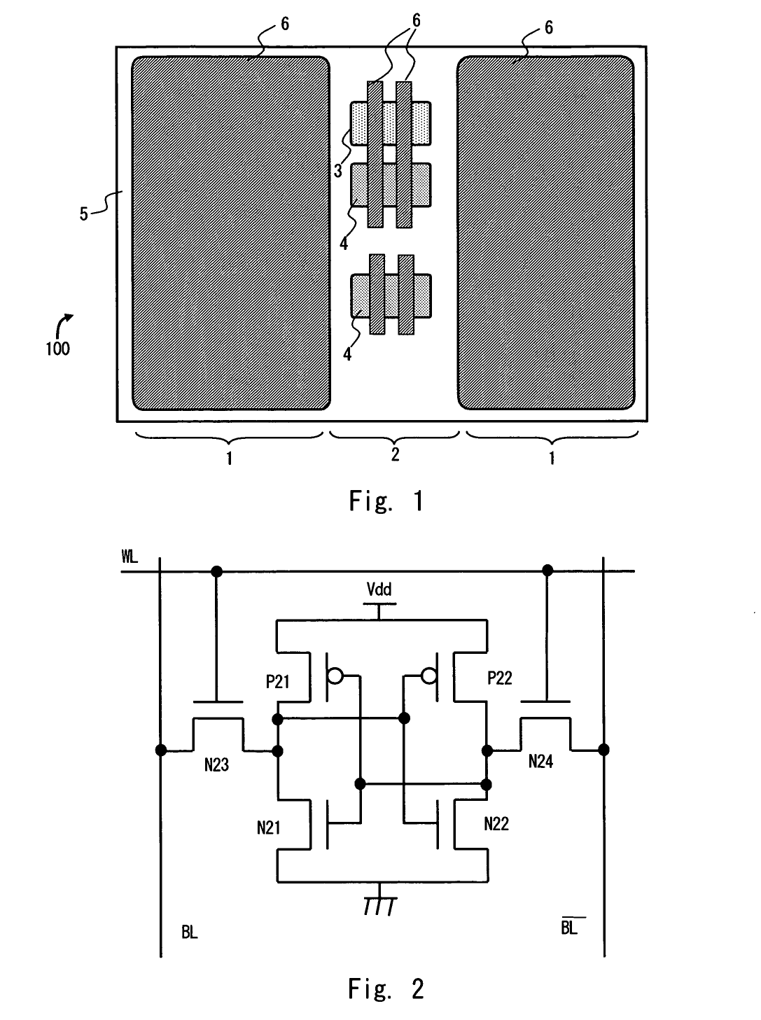

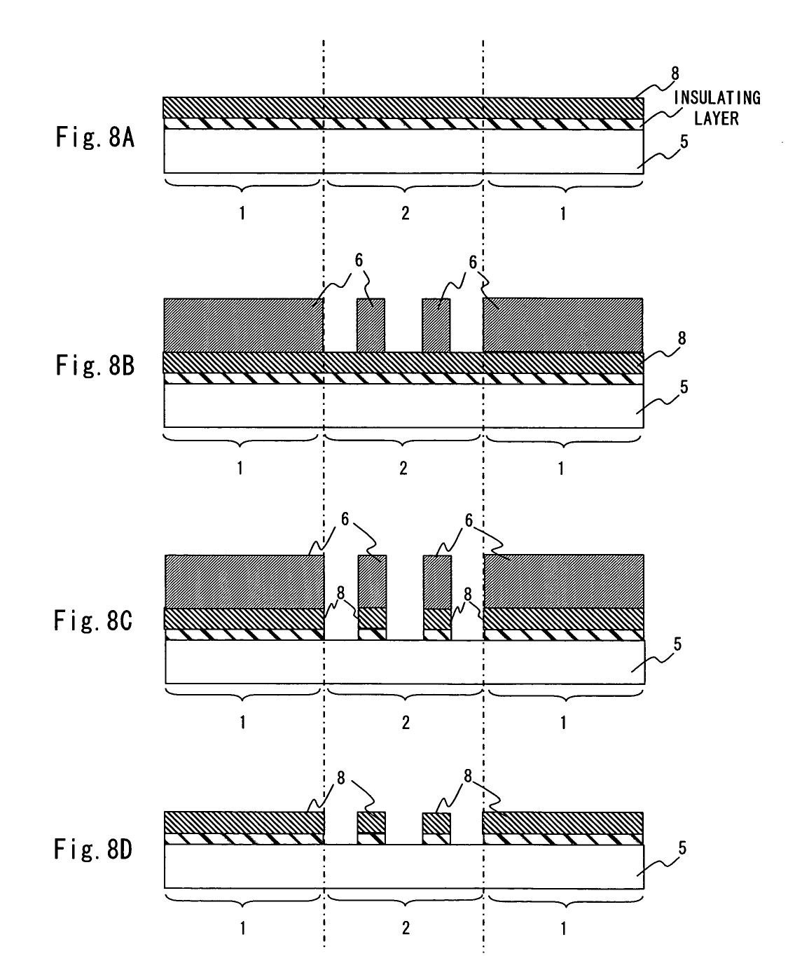

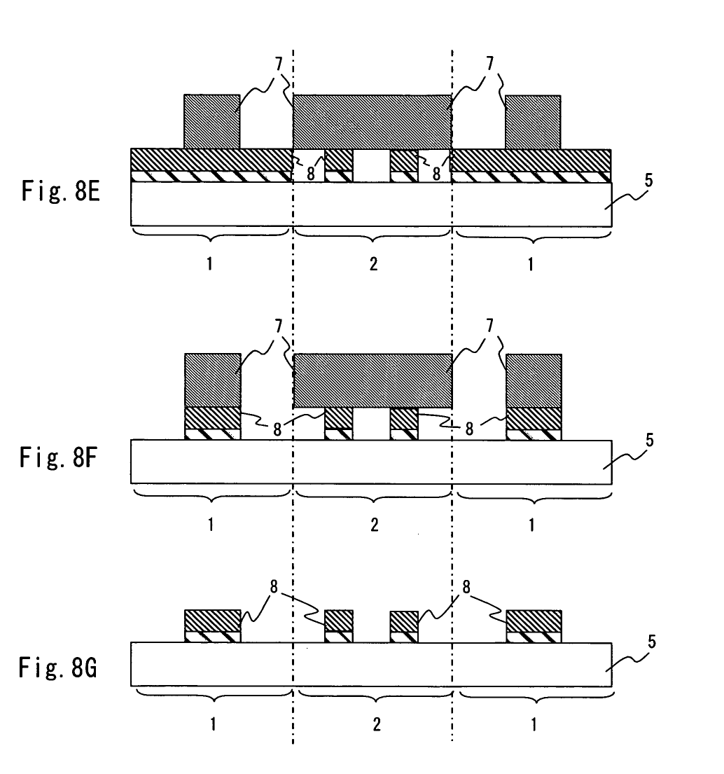

FIG. 1 is a plan view for explaining a manufacturing method according to a first embodiment of the present invention. FIGS. 8A to 8G are cross sectional views for explaining a manufacturing method according to a first embodiment of the present invention. A semiconductor device 100 of the first embodiment includes a region 1 (a first region) where a normal device such as a logic circuit is formed, and a region 2 (a second region) where a transistor pair is formed.

A transistor pair in a semiconductor device is described hereinafter in detail. FIG. 2 is a circuit diagram showing a SRAM memory cell. As shown in FIG. 2, a SRAM memory cell is generally formed by two drive transistors N21 and N22, two load transistors P21 and P22, and two transfer transistors N23 and N24. To improve characteristics of a SRAM cell, it is desirable that drive transistors, load transistors, and transfer transistors form transistor pairs having the same characteristics. In a semiconductor device having a SRAM, a region where the SRAM cell is formed corresponds to the region 2, which is the region transistor pairs are formed thereto. A region where other circuits are formed corresponds to the region 1 in FIG. 1.

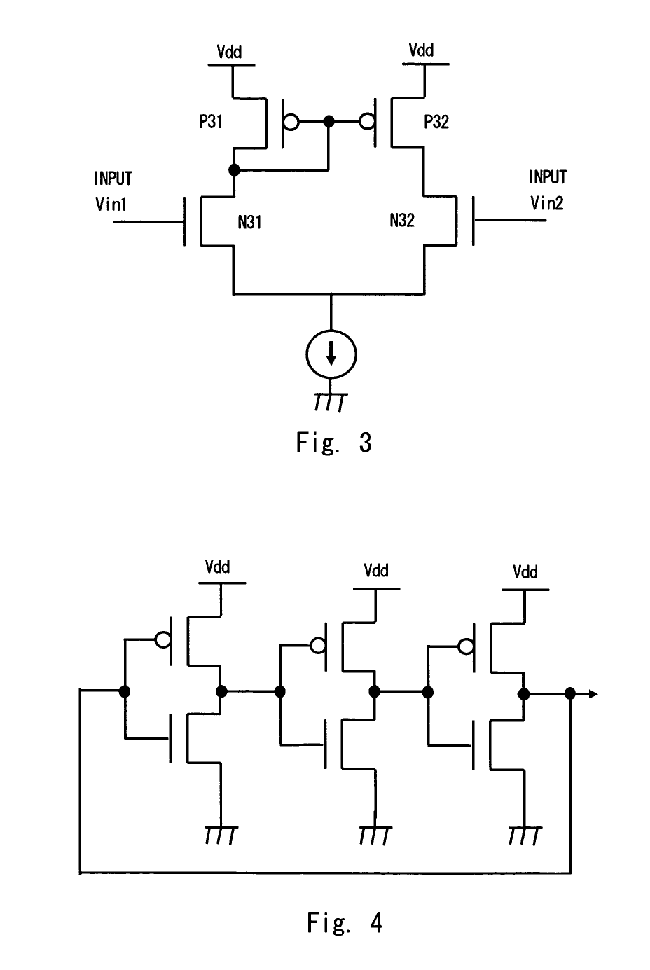

FIG. 3 is a circuit diagram showing a configuration of a differential amplifier circuit, which is one of differential circuits. In such a differential amplifier circuit, a transistor pair is formed by transistors N31 and N32 where differential signals Vin1 and Vin2 are inputted thereto. To perform an optimum differential operation, characteristics of the two transistors in an input circuit are desirably equivalent. Further, the circuit shown in FIG. 3 is a differential amplifier circuit having a current mirror. In a current mirror, P31 and P32 comprising the current mirror is formed as a transistor pair. Therefore, in a semiconductor device having such a differential input, a region where a differential input stage is formed corresponds to the region 2 where transistor pairs are formed.

FIG. 4 is a circuit diagram showing a configuration of a part of a ring oscillator, which is one of an oscillation circuit. A ring oscillator is a circuit connected with odd number of inverter stages. In an ideal ring oscillator, desirably characteristics of P type transistors P41, P42, and P43 are equivalent, and also characteristics of N type transistors N41, N42, and N43 are equivalent. Accordingly in a ring oscillator, a region where inverters are formed corresponds to a region where transistors with the same characteristic are formed (in the explanation below, it corresponds to the region 2 where transistor pairs are formed).

As described in the foregoing, the semiconductor device 100 of this embodiment includes the region 2 where transistor pairs are formed and a region 1 where other MISFETs are formed.

In the semiconductor device 100 shown in FIG. 1, an N type diffusion layer 3 and a P type diffusion layer 4 are already formed over a semiconductor substrate 5 using known photolithography and etching techniques. At this time, a gate electrode material polysilicon 8 for example is formed over an entire surface of the semiconductor substrate 5 (See FIG. 8A). In a manufacturing method of this embodiment, a first mask 6 is formed over the gate electrode material. In FIG. 1, only diffusion layers 3 and 4, and the first mask 6 are illustrated for convenience. The first mask 6 is formed by photoresist, for example (See FIG. 8B). In this embodiment as shown in FIG. 1, the first mask 6 is formed to conform with the shape of gate electrodes. The first mask 6 is formed over an entire surface of the region 1 where other devices are formed (See FIG. 8B).

After the first mask is formed, an etching of gate electrode material for example by an anisotropic etching is performed (first etching process). Although a condition for etching varies depending on gate electrode material and gate interval, it is performed under a condition with the highest processing accuracy. The first etching process forms gate electrodes of a region where transistor pairs are formed (See FIG. 8C).

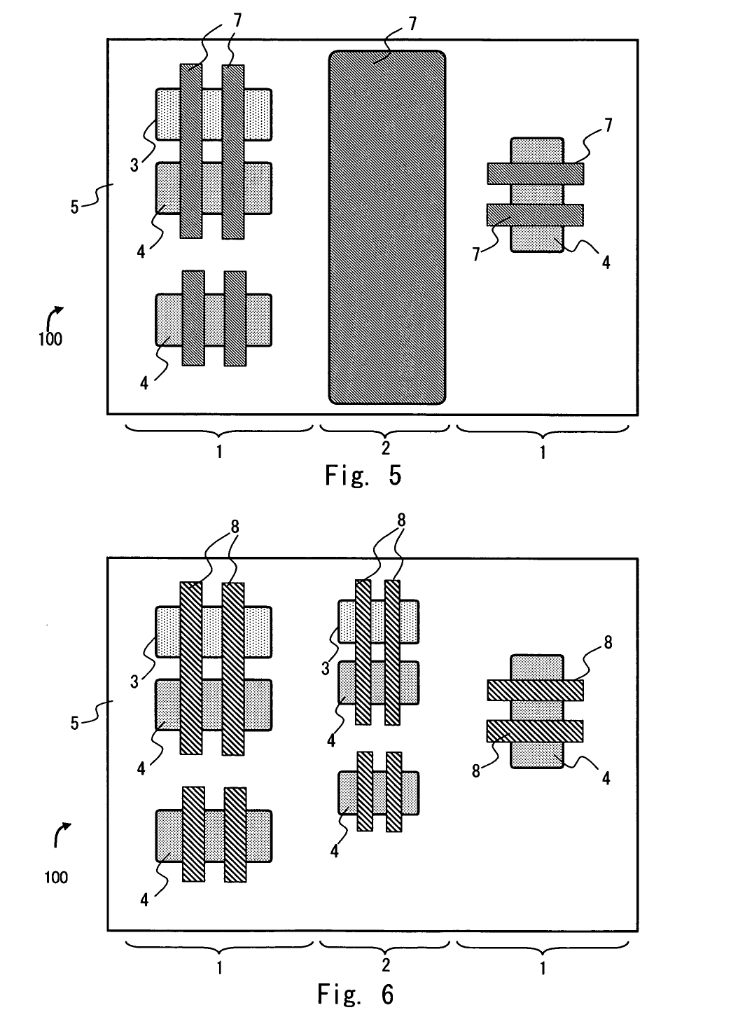

After the first etching process, the first mask 6 used for the first etching process is removed, and gate electrode material having the same shape as the first mask 6 shown in FIG. 1 remains (See FIG. 8D). In this embodiment, a second mask 7 is formed over gate electrode material formed in the same shape as the first mask 6 shown in FIG. 1. The second mask 7 is shown in FIG. 5 and FIG. 8E. As shown in FIG. 5 and FIG. 8E, the second mask 7 is formed over an entire surface of the region 2 where transistor pairs are formed. In the region 1, the second mask 7 is patterned to conform with the shape of gate electrodes being formed. An etching of gate electrode material (second etching process) is performed using the second mask 7 as a mask (See FIG. 8F).

Although a condition for etching varies depending on gate electrode material, it is performed under a condition with the highest efficiency considering an etching rate and fluctuation. The second etching process forms gate electrodes in the region 1 where a normal logic circuit is formed (See FIG. 8F). Then the second mask 7 is removed. FIG. 6 is a pattern diagram showing the semiconductor device 100 after the second mask 7 is removed (See FIG. 8G). As shown in FIG. 6, a gate electrode 8 is formed over the region 2 where transistor pairs are formed, and the region 1 where a normal logic circuit is formed, which are over the semiconductor substrate 5. After that, upper layer wiring and insulating film are formed as necessary to form the semiconductor device 100 (See FIG. 8G).

As described in detail, in the first embodiment of the present invention, an entire surface of the region other than the region where transistor pairs are formed (the region to form transistors having the same characteristics) is masked, and then etched to form gate electrodes of transistor pairs. Accordingly there is no influence from a fluctuation when forming a gate electrode as there is in a conventional technique, but a highly accurate etching focusing on processing accuracy can be achieved with one etching process on one layer.

In this embodiment, a gate electrode of a transistor comprising a pair is formed in one process by one etching process. It is extremely significant to have the same characteristic for a transistor pair. Specifically, by etching and forming gate electrodes of transistors to be paired up at the same time, characteristics of individual transistors comprising a transistor pair can be the same. Furthermore, one etching process forms one gate electrode, thereby not requiring a fine photolithography process only to an end of a gate.

Therefore in this embodiment, for a region where a transistor pair is to be formed with high processing accuracy and the same characteristic being demanded, an etching process is performed under the best condition for improving accuracy so as to form a gate electrode of a transistor comprising a pair. Gate electrodes pairing up to be a transistor pair are formed in the same process. After that a gate electrode of a normal logical circuit is formed in a different process. This allows to perform an etching most appropriate for gate electrode comprising a transistor pair.

In the above embodiment, a SRAM cell, a differential circuit, and an oscillation circuit are explained as a common example to include a transistor pair. However, the present invention can be applied to a case of forming characteristics of a plurality of transistors having the same characteristic. In this embodiment, the second etching process may be performed before the first etching process. Specifically, an identical effect can be achieved by performing a first etching process to form a mask over the region 2 where transistor pairs are formed, and then performing the second etching process to form a mask over the region 1 where a normal circuit is formed.

### Second Embodiment

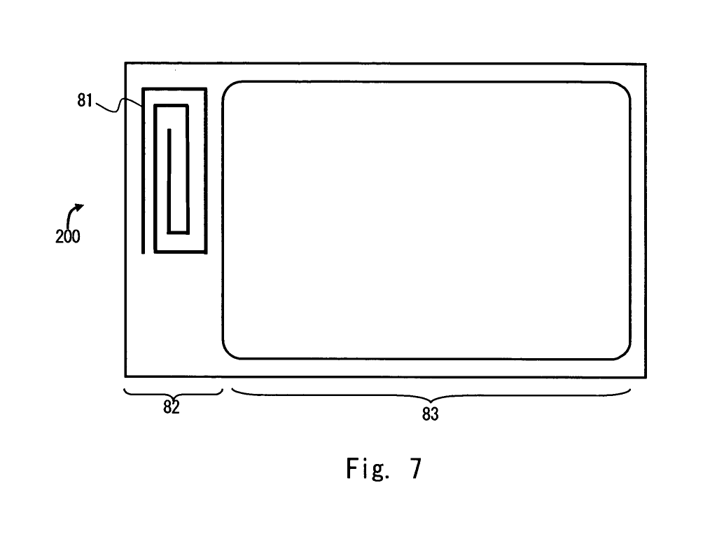

FIG. 7 is a view explaining a method of manufacturing a semiconductor device 200 of a second embodiment. In a semiconductor device of recent years, a passive device (capacitance, inductance, and resistance) is formed using a conductive layer such as a metal wiring. FIG. 7 is a pattern diagram showing a case of forming an inductance (coil) 81 using a conductive layer. The conductive layer forming the inductance 81 in this example is used as a wiring in other region of a semiconductor device. As described in the foregoing, the semiconductor device 200 of the second embodiment includes a passive device forming region 82 by metal wiring layer, and a normal metal wiring forming region 83. The metal wiring layer of the normal metal wiring forming region 83 only needs to be formed for satisfying design standard about a delay and resistance of wiring. On the other hand, to form a passive device by the same conductive layer as the metal wiring, a highly accurate processing is required because it operates as a circuit device. Thus in this embodiment, the first and the second etching processes are performed to the same metal wiring layer. For example in the first etching process, a mask such as resist is formed over an entire surface of the metal wiring forming region 83 (see FIG. 7), so that a mask based on a passive device is formed over the passive device forming region 82. Using the mask as a first mask, an etching is performed to form a passive device. The first etching process is performed under a condition with the highest accuracy according to a desirable shape of a pattern, density, and metal wiring material. In the second etching process, a mask is formed over an entire surface of the passive device forming region 82 and an etching is performed according to the second mask formed based on the wiring (not shown). In the second etching process, an etching condition that allows the most efficient etching in consideration of an etching rate and fluctuation, for example, is selected.

As described in the foregoing, by etching individually for the region where a passive device is formed and a region where a wiring is formed, it is possible to accurately form a passive device formed by metal wiring layer. Therefore a fluctuation in device characteristics is reduced, enabling to provide a highly accurate semiconductor device.

As described in detail about the embodiments, in the present invention, a region to be etched is divided into a plurality of regions according to characteristics of devices formed by etching, for example, to etch the regions under an optimum condition for the region. Although forming in this way increases the number of etching processes, it is possible to provide a highly accurate device.

In the foregoing embodiments, an example of dividing a region to be etched according to its functionality (for example transistor pair and passive device) is explained. However the region may be divided according to a density of the region to be etched. For example a region to be performed with the first etching process may be a region including the smallest gate or line interval. A region to be performed with the second etching process may be the other region. Otherwise a gate electrode layer or a conductive layer on a semiconductor substrate may be divided into a plurality of unit regions, to calculate an average density in each unit region from layout pattern. Then a region to be performed with the first etching process may be a region with its average line interval is less than or equal to a threshold, and a region to be performed with the second etching process may be a region with its average line interval is more than the threshold.

It is apparent that the present invention is not limited to the above embodiment and it may be modified and changed without departing from the scope and spirit of the invention.

What is claimed is:

1. A method for manufacturing a semiconductor device comprising:
performing a first etching process on a gate electrode layer to form a gate electrode of a first transistor group including a transistor pair; and
performing a second etching process different from the first etching on the gate electrode layer to form a gate electrode of a second transistor group.

2. The method for manufacturing a semiconductor device according to claim 1, wherein the first etching process is performed in a condition where an entire surface of a region to be formed with the second transistor group is masked.

3. The method for manufacturing a semiconductor device according to claim 1, wherein the second etching process is performed in a condition where an entire surface of a region to be formed with the first transistor group is masked.

4. The method for manufacturing a semiconductor device according to claim 2, wherein the second etching process is performed in a condition where an entire surface of a region to be formed with the first transistor group is masked.

5. The method for manufacturing a semiconductor device according to claim 1, wherein the first transistor group includes a SRAM cell.

6. The method for manufacturing a semiconductor device according to claim 1, wherein the first transistor group includes a differential circuit.

7. The method for manufacturing a semiconductor device according to claim 1, wherein the first transistor group includes an oscillation circuit.

8. The method for manufacturing a semiconductor device according to claim 1, wherein the transistor pair is a transistor comprising at least one of a load transistor, a drive transistor, or a transfer transistor in a SRAM cell.

9. A method of manufacturing a semiconductor device comprising:
performing a first etching process on a wiring layer to form a passive device formed by wiring layer; and
performing a second etching process different from the first etch to form a line having a specified shape.

10. The method of manufacturing a semiconductor device according to claim 9, wherein the first etching process is performed in a condition where an entire surface of a region to be formed with the wiring is masked.

11. The method of manufacturing a semiconductor device according to claim 9, wherein the second etching process is performed in a condition where an entire surface of a region to be formed with the passive device is masked.

12. The method of manufacturing a semiconductor device according to claim 10, wherein the second etching process is performed in a condition where an entire surface of a region to be formed with the passive device is masked.
